(19) United States
(12) Patent Application Publication
(10) Pub. No.: US 2026/0086454 A1
(43) Pub. Date: Mar. 26, 2026

(54) PATTERN FORMING METHOD, MOLD, SYSTEM, AND ARTICLE MANUFACTURING METHOD

(71) Applicant: CANON KABUSHIKI KAISHA, Tokyo (JP)

(72) Inventors: SHINTARO SUZUKI, Tochigi (JP); YOSUKE MURAKAMI, Tochigi (JP)

(21) Appl. No.: 19/334,098

(22) Filed: Sep. 19, 2025

(30) Foreign Application Priority Data
Sep. 25, 2024 (JP) 2024-166565

(51) Int. Cl. G03F 7/00

(52) U.S. Cl. CPC G03F 7/0002

(57) ABSTRACT

A pattern forming method of forming patterns on a plurality of shot regions on a substrate, the method including forming a film including a bank portion surrounding each of the plurality of shot regions on the substrate, and forming the pattern by placing an imprint material on an inside region surrounded by the bank portion on the film formed in the forming the film and bringing the imprint material into contact with a mold.

### BACKGROUND

### Field of the Technology

The present disclosure relates to a pattern forming method, a mold, a system, and an article manufacturing method.

### Description of the Related Art

A microfabrication technique of molding an imprint material placed (supplied) on a substrate with a mold has attracted attention as a lithography technique for manufacturing devices such as semiconductor elements and liquid crystal display elements. There is known an imprint apparatus that forms a pattern of an imprint material by curing the imprint material while a mold on which a pattern is formed on its surface is in contact with the imprint material placed on a substrate. There is also known a planarization apparatus that forms a planarization film (underlying film) having a flat surface by putting droplets of an imprint material on a substrate having unevenness and curing the imprint material while a mold having a flat surface is in contact with the imprint material.

In an imprint apparatus, a mold is pressed against an imprint material on a substrate. At this point of time, since the imprint material has fluidity, the imprint material sometimes bleeds from the mold and adheres to its side surface (side wall), that is, so-called bleeding sometimes occurs. If that part (adhering substance) of the imprint material which adheres to the side surface of the mold drops on the substrate at some (unintentional) timing, the adhering substance that has dropped on the substrate may come into contact with the mold to damage the mold.

Japanese Patent Laid-Open No. 2013-33878 has proposed a technique for suppressing the bleeding of an imprint material. Japanese Patent Laid-Open No. 2013-33878 discloses a mold that helps an imprint material to uniformly spread along the edges of a mold and is provided with an auxiliary pattern for absorbing the extra part of the imprint material.

### SUMMARY

The present disclosure provides a technique advantageous in forming a pattern on a substrate.

According to one aspect of the present disclosure, there is provided a pattern forming method of forming patterns on a plurality of shot regions on a substrate, the method including forming a film including a bank portion surrounding each of the plurality of shot regions on the substrate, and forming the pattern by placing an imprint material on an inside region surrounded by the bank portion on the film formed in the forming the film and bringing the imprint material into contact with a mold.

Features of the present disclosure will become apparent from the following description of embodiments with reference to the attached drawings. The following description of embodiments are described by way of example.

### BRIEF DESCRIPTION OF THE DRAWINGS

FIG. 1 is a schematic view showing the arrangement of a film forming apparatus.

FIG. 2 is a schematic view showing the arrangement of an imprint apparatus.

FIG. 3 is a schematic view showing a substrate on which an underlying film is formed.

FIG. 4 is a schematic view showing an example of the arrangement of a mold used in a film forming apparatus.

FIGS. 5A to 5C are views for explaining an underlying film forming step.

FIGS. 6A to 6C are views for explaining an imprint step.

FIGS. 7A and 7B are schematic views showing an example of the arrangement of a bank portion of an underlying film.

FIGS. 8A to 8C are views for explaining an underlying film forming step.

FIGS. 9A to 9C are views for explaining an imprint step.

FIGS. 10A to 10C are views for explaining an underlying film forming step.

FIGS. 11A to 11C are views for explaining an imprint step.

FIGS. 12A and 12B are views showing an example of the arrangement of a groove portion of an underlying film.

FIGS. 13A to 13C are schematic views showing a substrate on which an underlying film including an outer peripheral bank portion is formed.

FIG. 14 is a schematic view showing an example of the arrangement of a mold used in a film forming apparatus.

FIG. 15 is a view for explaining an example of the function of an underlying film formed on a substrate.

FIG. 16 is a schematic view showing the arrangement of an imprint system as one aspect of the present disclosure.

FIG. 17 is a flowchart for explaining the overall operation of the imprint system.

FIG. 18 is a flowchart for explaining the operation of a film forming apparatus in the imprint system.

FIG. 19 is a flowchart for explaining the operation of an imprint apparatus in the imprint system.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

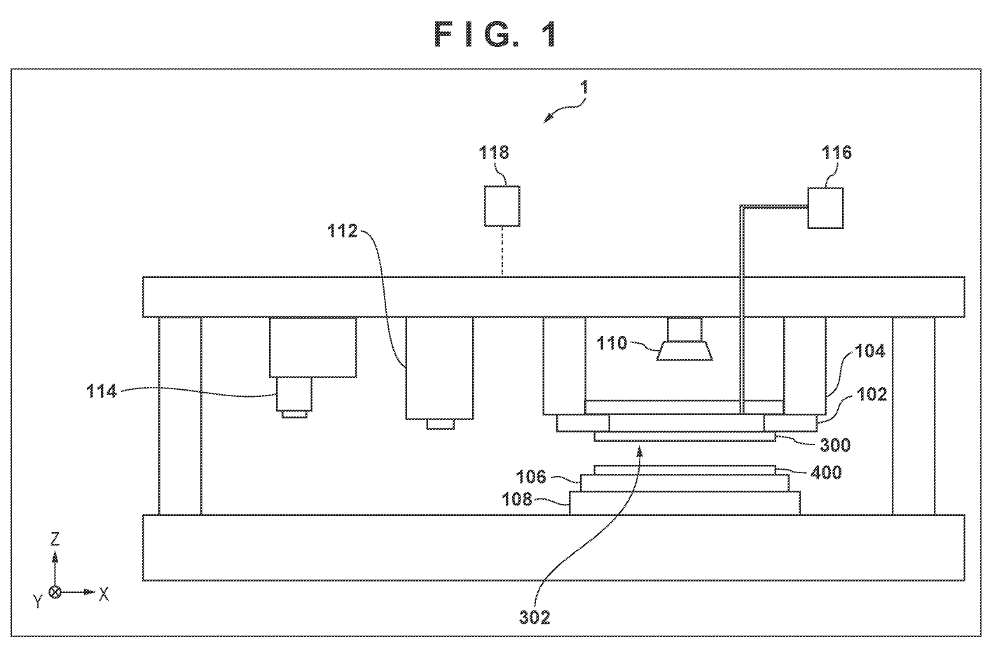

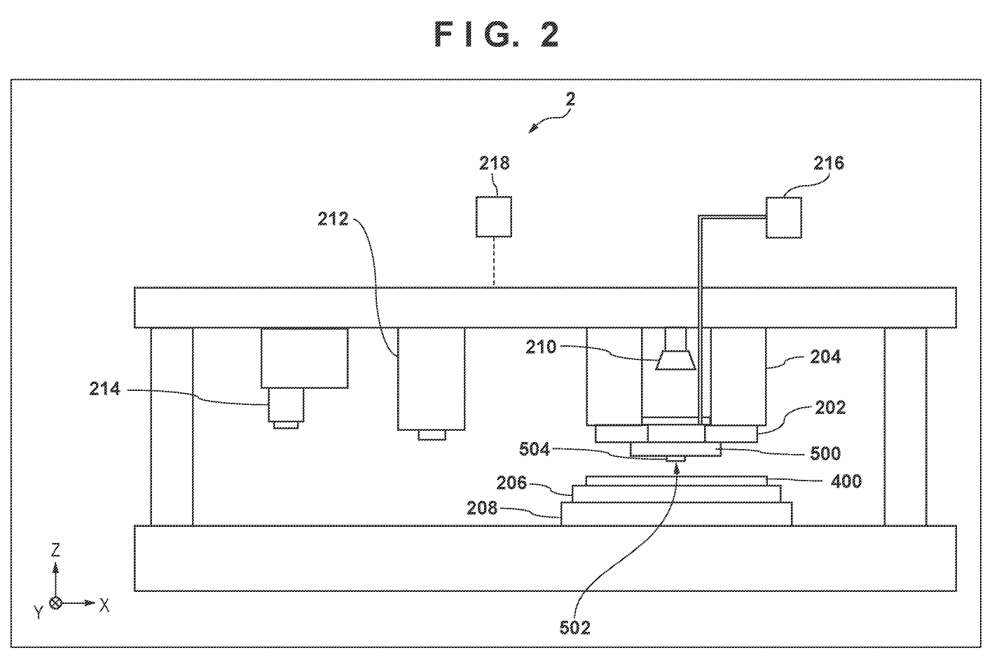

A film forming apparatus 1 and an imprint apparatus 2 which are used in a pattern forming method as one aspect of the present disclosure will be described with reference to FIGS. 1 and 2. FIG. 1 is a schematic view showing the arrangement of the film forming apparatus 1. FIG. 2 is a schematic view showing the arrangement of the imprint apparatus 2.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively.

The film forming apparatus 1 will be described first. The film forming apparatus 1 is used in a manufacturing step for devices such as semiconductor elements, liquid crystal display elements, and magnetic storage media as articles and forms a film by molding the curable composition placed on a substrate by using a mold. In the present embodiment, the film forming apparatus 1 is embodied as a planarization apparatus that forms an underlying film for reducing (planarizing) a stepped portion on a substrate by bringing a mold into contact with the curable composition placed on the substrate and curing the curable composition. The film forming apparatus 1 uses a mold having dimensions (size) that cover the entire region of a substrate and forms an underlying film made of a cured product of a curable composition on the entire region of the substrate. The curable composition for forming the underlying film includes a material used to form a spin on carbon (SOC) film.

The film forming apparatus 1 uses a light curing method as a curable composition curing method but may use a curing method of curing a curable composition using another type of energy (for example, heat). As shown in FIG. 1, the film forming apparatus 1 includes a mold holding unit 102, a mold driving unit 104, a substrate holding unit 106, a substrate driving unit 108, an irradiation unit 110, an alignment measurement unit 112, a placement unit 114, a pressurizing unit 116, and a control unit 118.

The mold holding unit 102 has a function of holding a mold 300. The mold holding unit 102 holds the mold 300 by, for example, attracting the outer peripheral region of the reverse surface of the mold 300 by vacuum suction or electrostatic force.

The mold 300 has, for example, a circular flat shape. The mold 300 is a pressing member that has a contact surface 302, which comes into contact with the curable composition placed on a substrate to form an underlying film, and presses the curable composition through the contact surface 302. The contact surface 302 of the mold 300 has an area larger than that of a substrate 400 (its surface) and can collectively presses the entire region of the substrate 400. Accordingly, in the present embodiment, an underlying film covering the entire region of the substrate 400 is formed by pressing the curable composition placed on the substrate with the mold 300.

The mold driving unit 104 drives the mold holding unit 102 (the mold 300 held by the mold holding unit 102). The mold driving unit 104 is configured to drive the mold holding unit 102 in a direction (the Z direction) so as to bring the mold 300 and the substrate 400 close or away from each other. Accordingly, the mold driving unit 104 implements the operation of bringing (pressing) the mold 300 into contact with the curable composition on the substrate and the operation of separating the mold 300 from the curable composition on the substrate. It is, however, preferable that the mold driving unit 104 be configured to drive the mold holding unit 102 in a plurality of directions (for example, three directions, namely, the Z direction, the θX direction, and the θY direction, preferably six directions, namely, the X direction, the Y direction, the Z direction, the θX direction, the θY direction, and the θZ direction).

The substrate holding unit 106 holds the substrate 400. The substrate holding unit 106 holds the substrate 400 by, for example, attracting the reverse surface of the substrate 400 with vacuum suction or electrostatic force.

The substrate driving unit 108 drives the substrate holding unit 106 (the substrate 400 held by the substrate holding unit 106). The substrate driving unit 108 is configured to drive the substrate holding unit 106 in, at least, the X direction and the Y direction. It is, however, preferable that the substrate driving unit 108 be configured to drive the substrate holding unit 106 in a plurality of directions (for example, three directions, namely, the Z direction, the θX direction, and the θY direction, preferably six directions, namely, the X direction, the Y direction, the Z direction, the θX direction, the θY direction, and the θZ direction).

The irradiation unit 110 irradiates a curable composition on a substrate with light curing the curable composition through the mold 300. The irradiation unit 110 includes, for example, a light source and an optical system that guides light emitted from the light source to the curable composition on the substrate.

The alignment measurement unit 112 measures the position (the position in the X direction and the Y direction) of the substrate 400 held by the substrate holding unit 106. The alignment measurement unit 112 measures the position of the substrate 400, for example, the position of each shot region on the substrate by detecting (observing) the alignment marks provided on the substrate 400.

The placement unit 114 includes a dispenser that puts droplets of a curable composition (discharges droplets) and places (supplies) a curable composition on a substrate. The placement unit 114 uses, for example, a piezo jet scheme or microsolenoid scheme and can place droplets of a curable composition on a substrate in a very small volume of about 1 picoliter.

The pressurizing unit 116 deforms the mold 300 held by the mold holding unit 102 into a convex shape (downward convex shape) toward the substrate 400 by applying pressure (positive pressure) to the reverse surface of the mold 300. This makes it possible to bring, first, the central portion of the mold 300 into contact with a curable composition when bringing the mold 300 into contact with the curable composition on the substrate.

The control unit 118 is formed of, for example, a computer (information processing apparatus) including a CPU and a memory and comprehensively controls each unit of the film forming apparatus 1 in accordance with programs stored in a storage unit or the like. The control unit 118 controls the film formation processing of forming an underlying film on a substrate using the mold 300 by controlling each unit of the film forming apparatus 1.

The imprint apparatus 2 will be described next. The imprint apparatus 2 is used in a manufacturing step for devices such as semiconductor elements, liquid crystal display elements, and magnetic storage media as articles and forms a pattern of an imprint material on a substrate using a mold. In the present embodiment, the imprint apparatus 2 forms a pattern of a cured product onto which the pattern of the mold is transferred by bringing the mold into contact with an uncured imprint material placed (supplied) on a substrate and applying curing energy to the imprint material.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25°C) of the imprint material is, for example, 1 mPa∙s (inclusive) to 100 mPa∙s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

According to the present embodiment, the imprint apparatus 2 uses a photo-curing method as an imprint material curing method but may use a curing method of curing an imprint material using another type of energy (for example, heat). As shown in FIG. 2, the imprint apparatus 2 includes a mold holding unit 202, a mold driving unit 204, a substrate holding unit 206, a substrate driving unit 208, an irradiation unit 210, an alignment measurement unit 212, a placement unit 214, a pressurizing unit 216, and a control unit 218.

The mold holding unit 202 has a function of holding a mold 500. The mold holding unit 202 holds the mold 500 by, for example, attracting the outer peripheral region of the reverse surface of the mold 500 by vacuum suction or electrostatic force.

The mold 500 has a rectangular outer shape. In the present embodiment, the mold 500 has an arrangement different from that of the mold 300. The mold 500 includes, on a surface opposing the substrate 400, a pattern region 502 provided with a pattern corresponding to a predetermined pattern (for example, a concave-convex pattern such as a circuit pattern) to be formed on the substrate 400. In the present embodiment, the mold 500 includes a mesa portion 504 that is a plateau-like portion protruding from the surrounding portion, and the pattern region 502 is provided on the upper surface of the mesa portion 504. The mesa portion 504 has an area equal to that of one shot region on the substrate. A core out may be engraved in the reverse surface of the mold 500 in a cylindrical concave shape.

The mold driving unit 204 drives the mold holding unit 202 (the mold 500 held by the mold holding unit 202). The mold driving unit 204 is configured to at least drive the mold holding unit 202 in a direction (the Z direction) to bring the mold 500 and the substrate 400 close or away from each other. Accordingly, the mold driving unit 204 implements the operation of bringing (pressing) the mold 500 into contact with the curable composition on the substrate and the operation of separating the mold 500 from the curable composition on the substrate. It is, however, preferable that the mold driving unit 204 be configured to drive the mold holding unit 202 in a plurality of directions (for example, three directions, namely, the Z direction, the θX direction, and the θY direction, preferably six directions, namely, the X direction, the Y direction, the Z direction, the θX direction, the θY direction, and the θZ direction).

The substrate holding unit 206 holds the substrate 400. The substrate holding unit 206 holds the substrate 400 by, for example, attracting the reverse surface of the substrate 400 by vacuum suction or electrostatic force.

The substrate driving unit 208 drives the substrate holding unit 206 (the substrate 400 held by the substrate holding unit 206). The substrate driving unit 208 is configured to drive the substrate holding unit 206 at least in the X direction and the Y direction. It is, however, preferable that the substrate driving unit 208 be configured to drive the substrate holding unit 206 in a plurality of directions (for example, three directions, namely, the Z direction, the θX direction, and the θY direction, preferably six directions, namely, the X direction, the Y direction, the Z direction, the θX direction, the θY direction, and the θZ direction).

The irradiation unit 210 irradiates, through the mold 500, an imprint material on a substrate with light that cures the imprint material. The irradiation unit 210 includes, for example, a light source and an optical system that guides the light emitted from the light source to the imprint material on the substrate.

The alignment measurement unit 212 measures the position (the positions in the X direction and the Y direction) of the substrate 400 held by the substrate holding unit 206. The alignment measurement unit 212 measures the position of the substrate 400, for example, the position of each shot region on the substrate, by detecting (observing) an alignment mark provided on the substrate 400.

The placement unit 214 includes a dispenser that puts droplets of an imprint material (discharges droplets) and places (supplies) the imprint material onto substrate. The placement unit 114 uses, for example, a piezo jet scheme or microsolenoid scheme and can place droplets of an imprint material on a substrate in a very small volume of about 1 picoliter.

The pressurizing unit 216 deforms the mold 500 held by the mold holding unit 202 into a convex shape (downward convex shape) toward the substrate 400 by applying pressure (positive pressure) to the reverse surface of the mold 500. In the present embodiment, the pressurizing unit 216 deforms the mesa portion 504 of the mold 500 by increasing and decreasing the pressure of the space defined by the core out of the mold 500 and a seal member. This makes it possible to bring, first, the central portion of the mesa portion 504 of the mold 500 (the pattern region 502) into contact with the imprint material when bringing the mold 500 into contact with the imprint material on the substrate.

The control unit 218 is formed of, for example, a computer (information processing apparatus) including a CPU and a memory and comprehensively controls each unit of the imprint apparatus 2 in accordance with programs stored in a storage unit or the like. The control unit 218 controls the imprint processing of forming a pattern of an imprint material on each shot region of the substrate 400 using the mold 500 by controlling each unit of the imprint apparatus 2.

The imprint processing includes the contact step of bringing an imprint material on a substrate into contact with the mold 500. In this step, the imprint material is pressed against the mold 500. Accordingly, this may cause the imprint material on the substrate to protrude from the mold 500 (the upper surface of the mesa portion 504) and adhere to a side surface of the mold 500, more specifically, a side surface (side wall) of the mesa portion 504, that is, so-called bleeding may occur. That part (adhering substance) of the imprint material which adheres to a side surface of the mesa portion 504 drops on the substrate and becomes a factor that damages the mold 500, and hence it is necessary to suppress bleeding in the contact step.

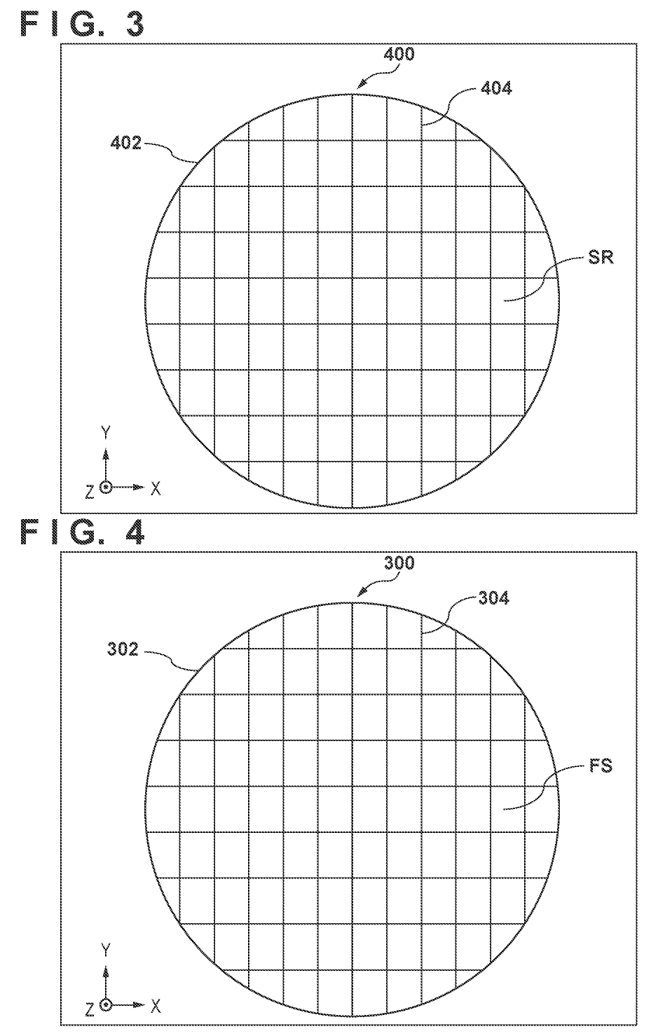

Accordingly, the present embodiment provides a pattern forming method that can form a pattern on each of a plurality of shot regions by using the film forming apparatus 1 and the imprint apparatus 2 while suppressing bleeding. First of all, as shown in FIG. 3, the film forming apparatus 1 forms, on the substrate 400, an underlying film 402 including a structure 404 for suppressing an imprint material from spreading wet to outside of the mold 500 (the pattern region 502 of the mesa portion 504) (first step). In the imprint apparatus 2, the imprint material is placed on the substrate 400 on which the underlying film 402 is formed, and a pattern of the imprint material is formed by bringing the imprint material into contact with the mold 500 (second step).

The pattern forming method according to the present embodiment will be described in detail below. As described above, the pattern forming method according to the present embodiment includes the underlying film forming step (film forming process) executed by the film forming apparatus 1 and the imprint step (imprint process) executed by the imprint apparatus 2.

As shown in FIG. 4, in the underlying film forming step of forming the underlying film 402 on the substrate 400, which is executed by the film forming apparatus 1, the mold 300 having a concave portion 304 formed in the contact surface 302 is used. The concave portion 304 is provided in the contact surface 302 so as to surround a region FS facing each of a plurality of shot regions SR on the substrate 400 while the mold 300 faces the substrate 400 in the film forming apparatus 1.

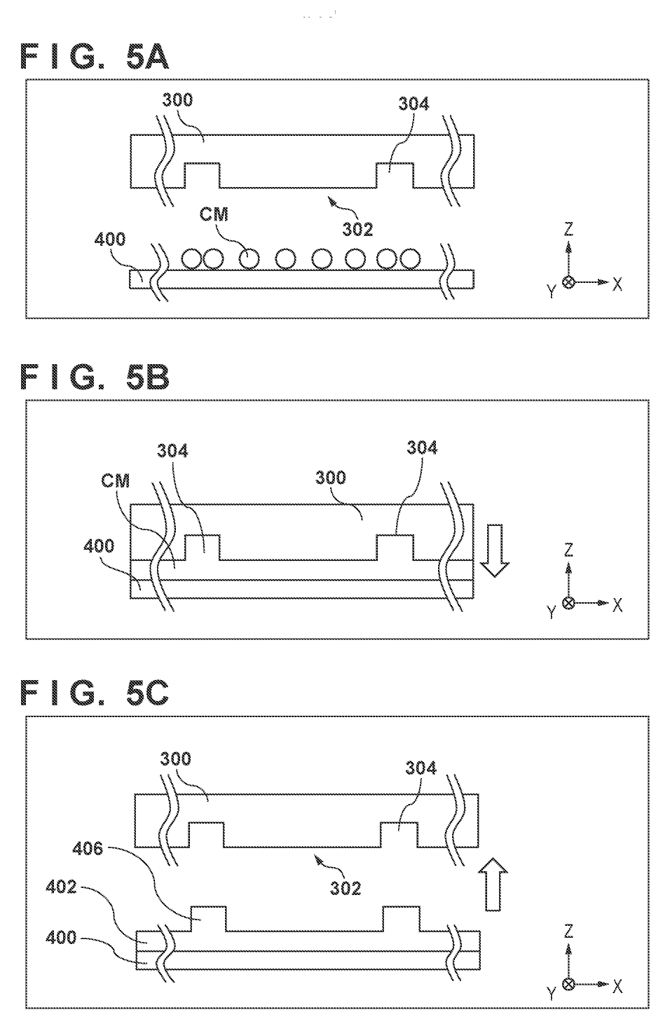

In the underlying film forming step, first of all, as shown in FIG. 5A, the placement unit 114 puts droplets of a curable composition CM on the substrate 400 held by the substrate holding unit 106 to place the curable composition CM (its droplets) on the substrate. As shown in FIG. 5B, the mold driving unit 104 is then driven to bring (press) the mold 300 (the contact surface 302 of the mold 300) held by the mold holding unit 102 into contact with the curable composition CM placed on the substrate. While the curable composition CM on the substrate is in contact with the mold 300, the irradiation unit 110 irradiates the curable composition CM with light to cure the curable composition CM. As shown in FIG. 5C, the mold driving unit 104 is driven to separate the mold 300 from the cured curable composition CM on the substrate. This forms, on the substrate, the underlying film 402 including a bank portion 406 corresponding to the concave portion 304 of the mold 300. The bank portion 406 is an example of the structure 404 for suppressing the imprint material on the substrate from spreading and is formed to surround each shot region of the substrate 400.

In this manner, in the underlying film forming step, the underlying film 402 covering the entire region of the substrate 400 is formed by pressing the curable composition CM placed on the substrate with the mold 300 having an area larger than that of the substrate 400. In this case, since the concave portion 304 is formed in the contact surface 302 of the mold 300, the bank portion 406 surrounding each of the plurality of shot regions of the substrate 400 is formed on the underlying film 402 formed on the substrate.

As described above, in the imprint step of forming the pattern on the substrate 400 on which the underlying film 402 is formed, which is executed by the imprint apparatus 2, the mold 500 provided with the mesa portion 504 including the pattern region 502 is used.

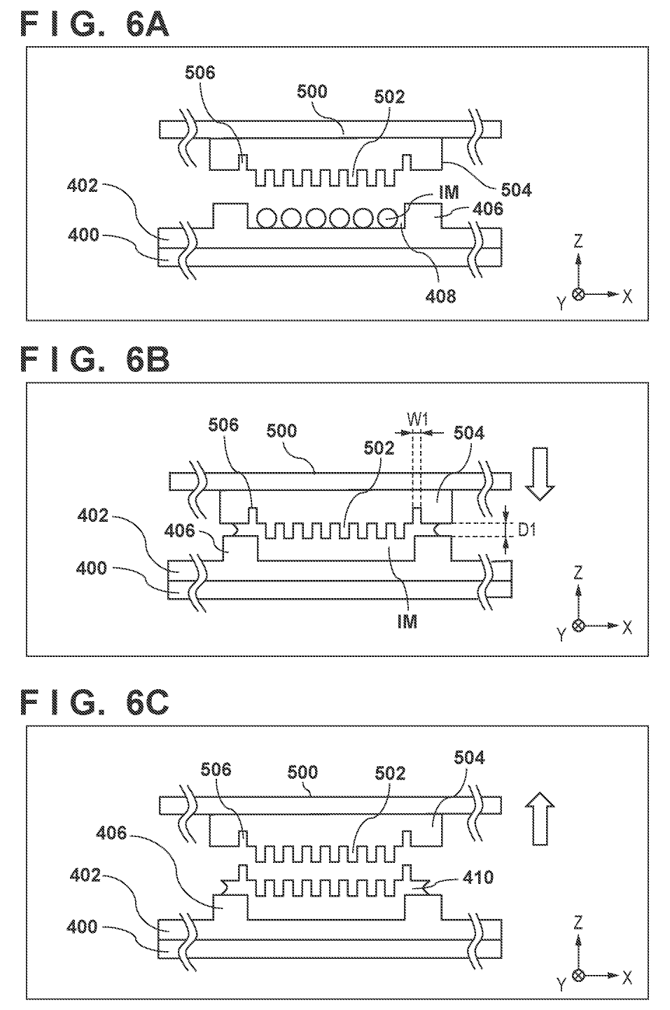

In the imprint step, as shown in FIG. 6A, the placement unit 214 places an imprint material IM (its droplets) on the substrate by putting droplets of the imprint material IM on the substrate 400 held by the substrate holding unit 206. More specifically, the imprint material IM is placed in the inside region 408 surrounded by the bank portion 406 of the underlying film 402 formed on the substrate. As shown in FIG. 6B, the mold driving unit 204 is then driven to bring (press) the mold 500 (the pattern region 502 of the mold 500) held by the mold holding unit 202 into contact with the imprint material IM placed in the region 408 on the substrate (underlying film). While the mold 500 is in contact with the imprint material IM placed in the region 408 on the substrate, the irradiation unit 210 irradiates the imprint material IM with light to cure the imprint material IM. As shown in FIG. 6C, the mold driving unit 204 is driven to separate the mold 500 from the imprint material IM cured on the substrate. This forms a pattern 410 of the imprint material IM corresponding to the pattern of the mold 500 on the substrate.

In this manner, in the imprint step, the pattern 410 of the imprint material IM is formed in a shot region of the substrate 400 by pressing the imprint material IM placed on the region 408 on the substrate with the mold 500 including the pattern region 502 on the mesa portion 504. In this case, when the mold 500 is pressed against the imprint material IM, the imprint material IM spreads along the upper surface of the mesa portion 504 of the mold 500, as shown in FIG. 6B. In the present embodiment, however, since the underlying film 402 is provided with the bank portion 406 surrounding the shot region, the bank portion 406 suppresses the imprint material IM from spreading and suppresses (prevents) the imprint material IM from protruding from the upper surface of the mesa portion 504. It is, therefore, possible to suppress the imprint material IM from crawling up and adhering to a side surface of the mesa portion 504 of the mold 500.

In addition, as shown in FIGS. 6A to 6C, the mold 500 (the mesa portion 504 of the mold 500) is preferably provided with a concave portion 506 surrounding the pattern region 502. The concave portion 506 is provided in the mold 500 so as to face the bank portion 406 of the underlying film 402 through the imprint material IM while the mold 500 faces the substrate 400 in the imprint apparatus 2. This can make the imprint material IM stay in the concave portion 506 when the imprint material IM spreads along the upper surface of the mesa portion 504 of the mold 500 as the mold 500 is pressed against the imprint material IM. Accordingly, it is possible to further suppress the imprint material IM from protruding from the upper surface of the mesa portion 504.

Note that while the mold 500 faces the substrate 400, the concave portion 506 of the mold 500 may face the inside region 408 surrounded by the bank portion 406 of the underlying film 402 through the imprint material IM. This can also make the imprint material IM spreading along the upper surface of the mesa portion 504 of the mold 500 stay in the concave portion 506 and further suppress the imprint material IM from protruding from the upper surface of the mesa portion 504.

In addition, as shown in FIG. 6B, a width W1 of the concave portion 506 provided in the mold 500 is preferably smaller than a distance D1 between the bank portion 406 of the underlying film 402 and the upper surface of the mesa portion 504 of the mold 500 while the mold 500 is in contact with the imprint material IM on the substrate. This makes the imprint material IM preferentially enter the concave portion 506 due to capillary action when the mold 500 is pressed against the imprint material IM, thereby further suppressing the imprint material IM from protruding from the upper surface of the mesa portion 504.

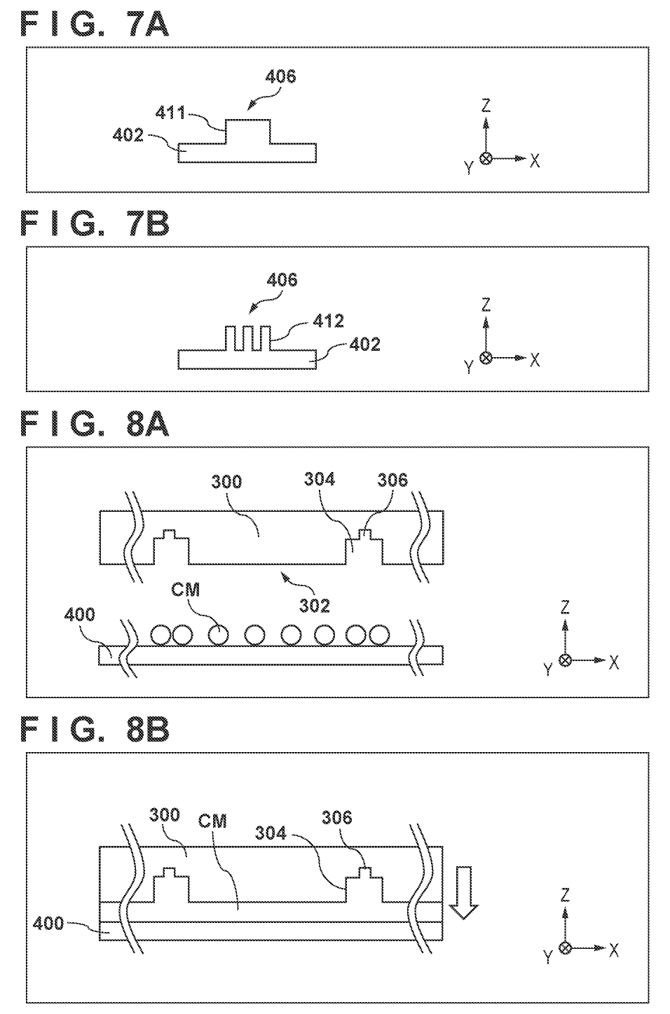

The bank portion 406 of the underlying film 402 may be formed of one convex pattern 411 as shown in FIG. 7A or formed of a plurality of convex patterns 412 as shown in FIG. 7B. Note that when the bank portion 406 of the underlying film 402 is formed of the plurality of convex patterns 412, the intervals between the plurality of convex patterns 412 are preferably smaller than the radius of a droplet of the imprint material IM placed on the substrate, numerically smaller than 10 μm. This makes the imprint material IM enter between the plurality of convex patterns 412 due to capillary action, and hence can further suppress the imprint material IM from protruding from the upper surface of the mesa portion 504.

The bank portion 406 of the underlying film 402 is preferably formed to have a height larger than that of the pattern formed on the pattern region 502 of the mesa portion 504 of the mold 500, numerically 5 nm or more. This makes it possible to effectively suppress the pattern region 502 of the mesa portion 504 of the mold 500 from coming into contact with the inside region 408 surrounded by the bank portion 406 of the underlying film 402 when the imprint material IM on the substrate is brought into contact with the mold 500.

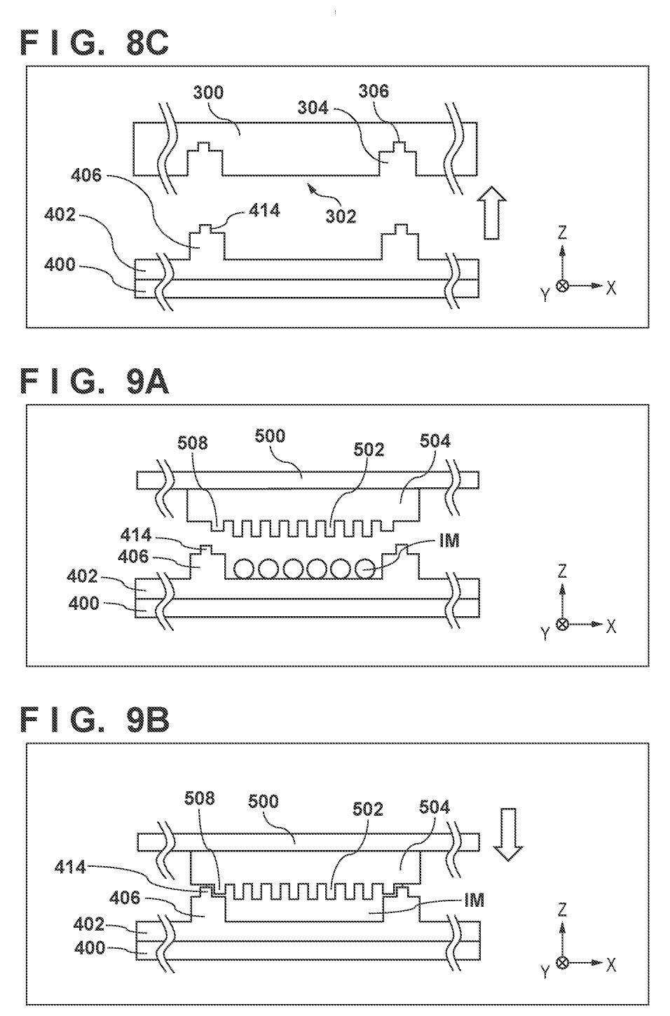

In the underlying film forming step, as shown in FIGS. 8A to 8C, the underlying film 402 may be formed so as to further include a convex portion 414 (first convex portion) on the upper surface of the bank portion 406. In this case, the convex portion 414 is formed on the upper surface of the bank portion 406 by using the mold 300 having a concave portion 306 further formed in the bottom surface of the concave portion 304 formed in the contact surface 302. Each step in the underlying film forming step is the same as each step in the underlying film forming step described with reference to FIGS. 5A to 5C except for the use of the mold 300 described above, and hence a detailed description thereof will be omitted here.

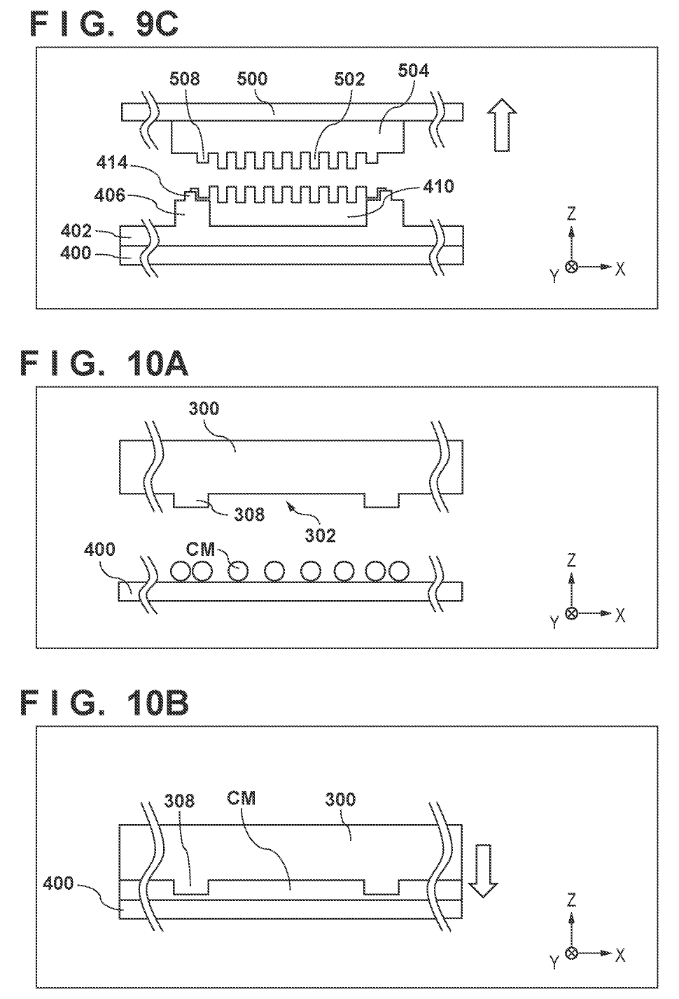

As shown in FIGS. 9A to 9C, in the imprint step for the substrate 400 on which the underlying film 402 is formed, which includes the bank portion 406 on which the convex portion 414 is formed, the mold 500 is used, which has a convex portion 508 (second convex portion) formed on the mesa portion 504 so as to surround the pattern region 502. Each step in the imprint step is basically the same as each step in the underlying film forming step described with reference to FIGS. 6A to 6C except for the use of the mold 500 described above. However, as shown in FIG. 9B, when the mold 500 is brought into contact with the imprint material IM placed on the region 408 on the substrate (on the underlying film), the convex portion 508 of the mold 500 acts on the bank portion 406 of the underlying film 402, specifically, on the convex portion 414 formed on the upper surface of the bank portion 406. In the present embodiment, while the mold 500 is brought into contact with the imprint material IM on the substrate, the convex portion 508 of the mold 500 is brought close (adjoined) to the convex portion 414 of the bank portion 406 of the underlying film 402 through the imprint material IM in X-Z plane view. More specifically, the convex portion 508 of the mold 500 faces the region of the upper surface of the bank portion 406 of the underlying film 402 in which the convex portion 414 is not present through the imprint material IM. In addition, a portion of a side surface of the convex portion 508 of the mold 500 faces a portion of a side surface of the convex portion 414 of the bank portion 406 of the underlying film 402 through the imprint material IM. Accordingly, in order to make the imprint material IM on the substrate reach an outside of the mesa portion 504 of the mold 500, the imprint material IM needs to pass through the gap between the convex portion 508 of the mold 500 and the region of the bank portion 406 in which the convex portion 414 is not present and the gap between the mold 500 and the convex portion 414 of the bank portion 406. These two gaps are very narrow and tend to increase in conductance as an index representing the flowability of the imprint material IM, and hence it is possible to further suppress the imprint material IM from protruding from the upper surface of the mesa portion 504. Note that the convex portion 508 of the mold 500 may be located inward from the convex portion 414 of the bank portion 406 of the underlying film 402 (see FIG. 9B) but may be located outward from the convex portion 414 in XY plane view.

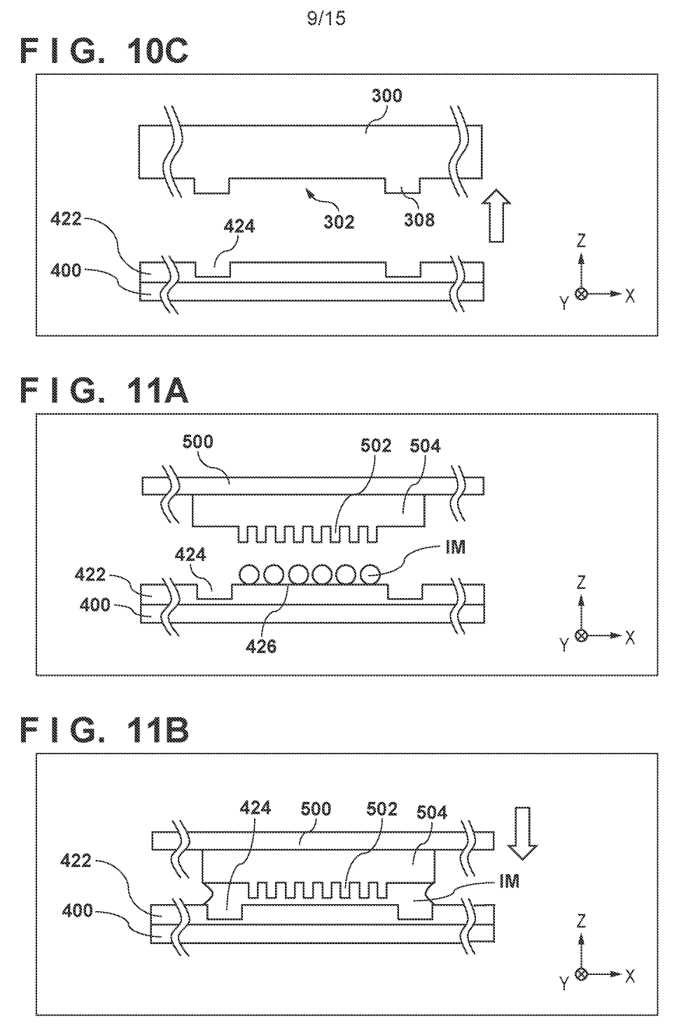

In the underlying film forming step of forming the underlying film 402 on the substrate 400, which is executed by the film forming apparatus 1, as shown in FIGS. 10A to 10C, the mold 300 having a convex portion 308 formed on the contact surface 302 instead of the concave portion 304 may be used. The contact surface 302 is provided with the convex portion 308 so as to surround the region FS facing each of the plurality of shot regions SR of the substrate 400 while the mold 300 faces the substrate 400 in the film forming apparatus 1. The following is a description of the underlying film forming step and the imprint step in a case where the mold 300 having the convex portion 308 provided on the contact surface 302 is used.

In the underlying film forming step, first of all, as shown in FIG. 10A, the curable composition CM (its droplets) is placed on a substrate by putting droplets of the curable composition CM from the placement unit 114 onto the substrate 400 held by the substrate holding unit 106. As shown in FIG. 10B, the mold driving unit 104 is driven to bring (press) the mold 300 (the contact surface 302 of the mold 300) held by the mold holding unit 102 into contact with the curable composition CM placed on the substrate. While the curable composition CM on the substrate is in contact with the mold 300, the irradiation unit 110 irradiates the curable composition CM with light to cure the curable composition CM. As shown in FIG. 10C, the mold driving unit 104 is driven to separate the mold 300 from the cured curable composition CM on the substrate. An underlying film 422 including a groove portion 424 corresponding to the convex portion 308 of the mold 300 is formed on the substrate. The groove portion 424 is an example of the structure 404 for suppressing the imprint material on the substrate from spreading and is formed to surround each shot region of the substrate 400.

In this manner, in the underlying film forming step, the underlying film 422 covering the entire region of the substrate 400 is formed by pressing the curable composition CM placed on the substrate with the mold 300 having an area larger than that of the substrate 400. In this case, since the convex portion 308 is provided on the contact surface 302 of the mold 300, the groove portion 424 surrounding each of the plurality of shot regions of the substrate 400 is formed in the underlying film 422 formed on the substrate.

In the imprint step of forming a pattern on the substrate 400 on which the underlying film 402 is formed, which is executed by the imprint apparatus 2, the mold 500 provided with the mesa portion 504 including the pattern region 502 is used, as described above.

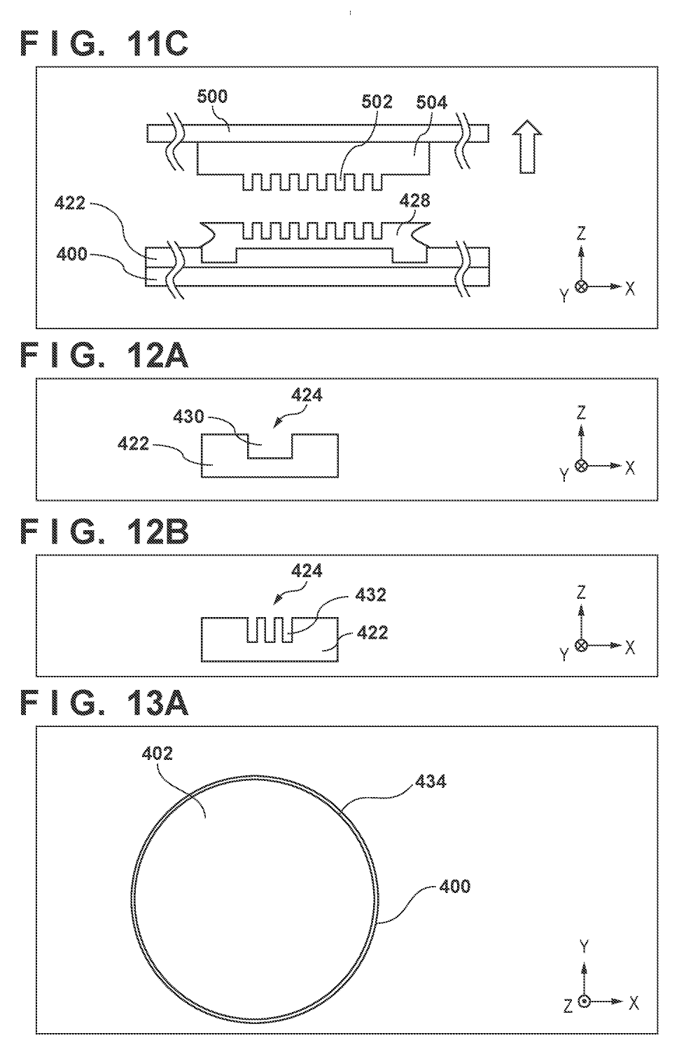

In the imprint step, as shown in FIG. 11A, the imprint material IM (its droplets) is placed on the substrate by putting droplets of the imprint material IM from the placement unit 214 onto the substrate 400 held by the substrate holding unit 206. More specifically, the imprint material IM is placed in an inside region 426 surrounded by the groove portion 424 of the underlying film 422 formed on the substrate. As shown in FIG. 11B, the mold driving unit 204 is then driven to bring (press) the mold 500 (the pattern region 502 of the mold 500) held by the mold holding unit 202 into contact with the imprint material IM placed on the region 426 on the substrate (the underlying film). In addition, while the imprint material IM placed on the region 426 on the substrate is in contact with the mold 500, the irradiation unit 210 irradiates the imprint material IM with light to cure the imprint material IM. Thereafter, as shown in FIG. 11C, the mold driving unit 204 is driven to separate the mold 500 from the cured imprint material IM on the substrate. This forms a pattern 428 of the imprint material IM corresponding to the pattern of the mold 500.

In this manner, in the imprint step, the pattern 428 of the imprint material IM is formed in a shot region of the substrate 400 by pressing the imprint material IM placed on the region 426 on the substrate against the mold 500 including the pattern region 502 of the mesa portion 504. In this case, when the mold 500 is pressed against the imprint material IM, the imprint material IM spreads along the upper surface of the mesa portion 504 of the mold 500, as shown in FIG. 11B. In the present embodiment, however, since the underlying film 402 is provided with the groove portion 424 surrounding a shot region, the groove portion 424 suppresses the imprint material IM from spreading and suppresses (prevents) the imprint material IM from protruding from the upper surface of the mesa portion 504. Accordingly, this makes it possible to suppress the imprint material IM from crawling up and adhering to a side surface of the mesa portion 504 of the mold 500.

The groove portion 424 of the underlying film 422 may be formed of one concave pattern 430 as shown in FIG. 12A or may be formed of a plurality of concave patterns 432 as shown in FIG. 12B. When the groove portion 424 of the underlying film 422 is formed of the plurality of concave patterns 432, the width of each of the plurality of concave patterns 432 is preferably smaller than the radius of a droplet of the imprint material IM placed on the substrate, numerically smaller than 10 μm. This makes the imprint material IM enter the plurality of concave patterns 432 due to capillary action and hence makes it possible to suppress the imprint material IM from protruding from the upper surface of the mesa portion 504.

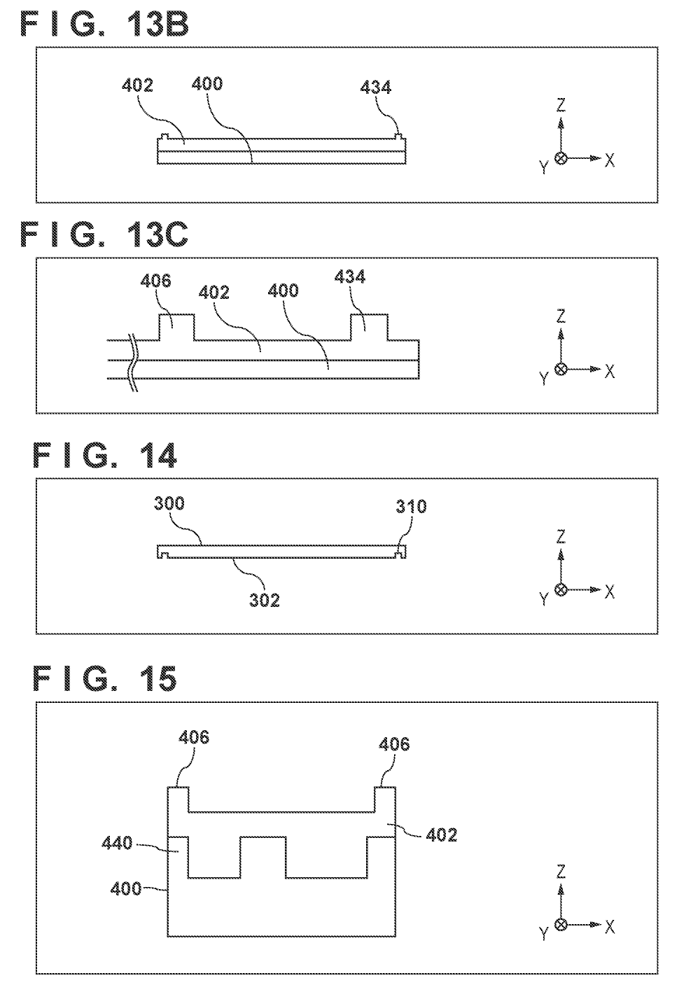

An outer peripheral bank portion 434 is preferably formed on an outer peripheral region of the underlying film 402 (the underlying film 422) formed on the substrate, as shown in FIGS. 13A, 13B, and 13C. The outer peripheral bank portion 434 is a bank portion that is provided along the outer periphery (edge) of the substrate 400 and surrounds the plurality of shot regions (all shot regions) of the substrate 400. Forming the outer peripheral bank portion 434 on the underlying film 402 (the underlying film 422) can suppress the imprint material IM from protruding to outside of the substrate 400 in a partial shot region (chipped shot region). In other words, the imprint material IM can be suppressed from protruding to outside of the substrate 400 by pressing the mold 500 against the imprint material IM to restrict the imprint material IM spreading along the upper surface of the mesa portion 504 of the mold 500 with the outer peripheral bank portion 434. In order to form the outer peripheral bank portion 434 on the underlying films 402 and 422, the mold 300 may be used, in which a concave portion 310 is formed in the outer peripheral region of the contact surface 302 along the outer periphery of the contact surface 302, as shown in FIG. 14. FIG. 13A is a plan view showing the substrate 400 on which the underlying film 402 including the outer peripheral bank portion 434 is formed. FIG. 13B is a sectional view of the substrate 400 shown in FIG. 13A. FIG. 13C is an enlarged view of the outer peripheral region of the substrate shown in FIG. 13A. FIG. 14 shows the mold 300 for forming the underlying film 402 including the outer peripheral bank portion 434.

In the present embodiment, as described above, the underlying film 402 (the underlying film 422) formed on the substrate preferably has a function as a planarization film for reducing (planarizing) the stepped portion on the substrate. More specifically, as shown in FIG. 15, filling a stepped portion 440 (concave-convex shape) of the substrate 400 with the underlying film 402 will reduce the stepped portion 440 on the substrate and planarize the surface of the substrate 400. Although the underlying film 402 has the bank portion 406 (the groove portion 424), forming the bank portion 406 (the groove portion 424) on the scribe line between shot regions of the substrate 400 can minimize the influence on the planarization.

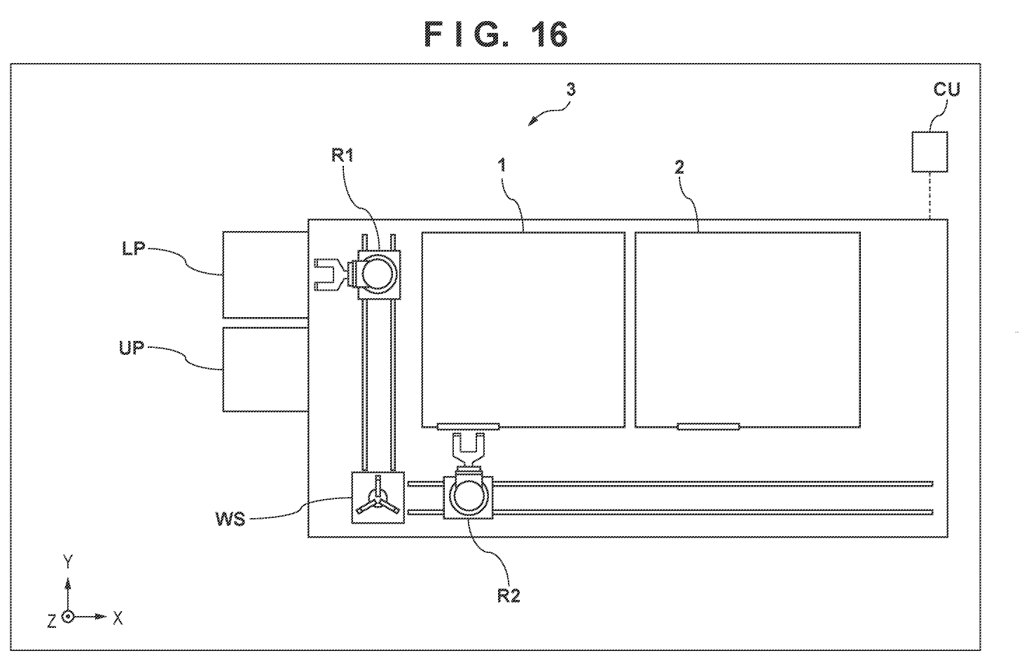

In implementing the pattern forming method according to the present embodiment, it is preferable to form an imprint system 3 including the film forming apparatus 1 and the imprint apparatus 2, as shown in FIG. 16. The imprint system 3 includes a load port LP in which a container containing a plurality of unprocessed substrates 400 is installed and an unload port UP in which a container containing a plurality of processed substrates 400 is installed. In addition, the imprint system 3 includes a first conveyance robot R1, a transfer stage WS, a second conveyance robot R2, and a main control unit CU.

The first conveyance robot R1 has a function of conveying the unprocessed substrate 400 from the load port LP to the transfer stage WS and a function of conveying the processed substrate 400 from the transfer stage WS to the unload port UP. The second conveyance robot R2 has a function of conveying the unprocessed substrate 400 from the transfer stage WS to the film forming apparatus 1 and a function of conveying the processed substrate 400 from the imprint apparatus 2 to the transfer stage WS.

The transfer stage WS is a stage for transferring the unprocessed substrate 400 between the load port LP (the first conveyance robot R1) and the film forming apparatus 1 (the second conveyance robot R2). The transfer stage WS is also a stage for transferring the processed substrate 400 between the imprint apparatus 2 (the second conveyance robot R2) and the unload port UP (the first conveyance robot R1). Note that the transfer stage WS may have a function of adjusting the angle of the substrate 400 upon detecting a notch of the substrate 400.

The main control unit CU is formed of, for example, a computer (information processing apparatus) including a CPU and a memory and comprehensively controls each unit of the imprint system 3 in accordance with programs stored in a storage unit or the like. The main control unit CU can also control the film forming apparatus 1 via the control unit 118 of the film forming apparatus 1 and control the imprint apparatus 2 via the control unit 218 of the imprint apparatus 2.

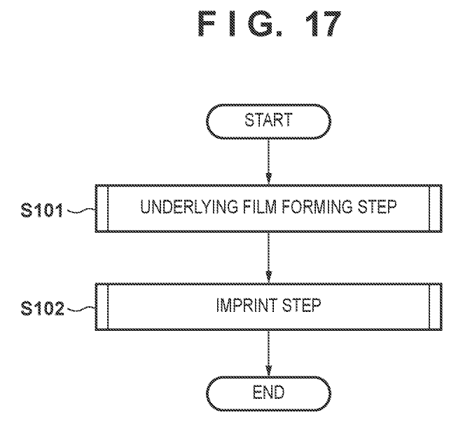

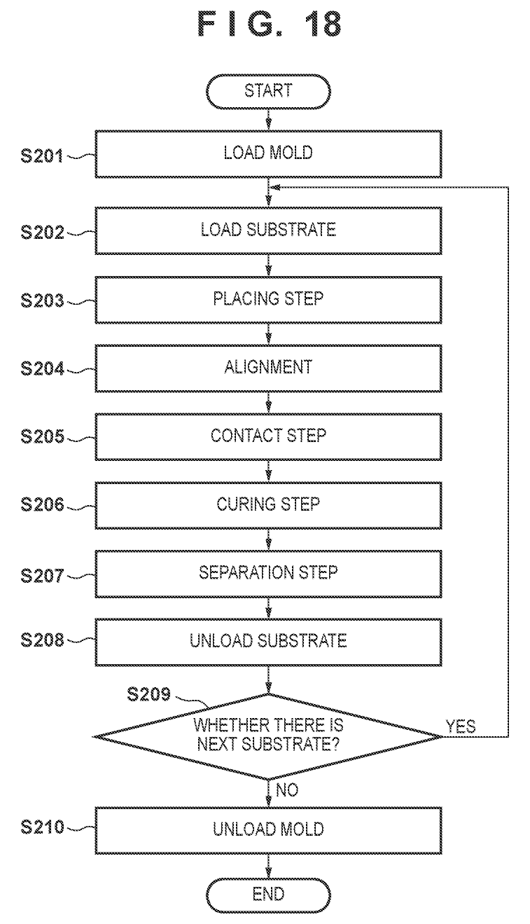

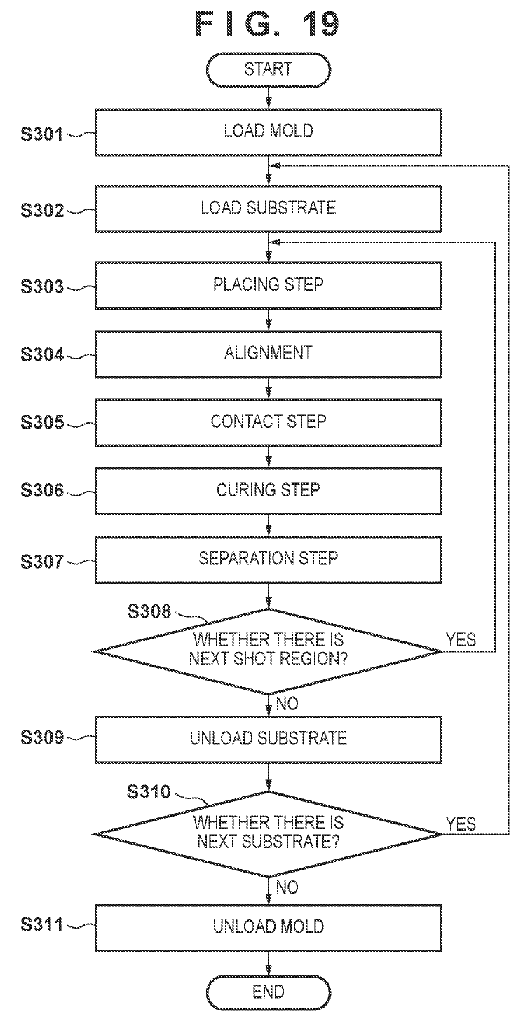

The operation of the imprint system 3 will be described with reference to FIGS. 17, 18, and 19. FIG. 17 is a flowchart for explaining the overall operation of the imprint system 3. FIG. 18 is a flowchart for explaining the operation of the film forming apparatus 1 in the imprint system 3. FIG. 19 is a flowchart for explaining the operation of the imprint apparatus 2 in the imprint system 3.

The overall operation of the imprint system 3 will be described first with reference to FIG. 17. This operation is an operation for implementing the pattern forming method. In step S101, the unprocessed substrate 400 is conveyed from the load port LP to the film forming apparatus 1 via the first conveyance robot R1, the transfer stage WS, and the second conveyance robot R2, and the film forming apparatus 1 executes an underlying film forming step (film forming process). In step S102, the substrate 400 (the processed substrate 400) on which the underlying film 402 (or 422) is formed is conveyed from the film forming apparatus 1 to the imprint apparatus 2, and the imprint apparatus 2 executes an imprint step (imprint process). The substrate 400 on which the pattern 410 (or 428) is formed by the imprint apparatus 2 is conveyed from the imprint apparatus 2 to the unload port UP via the second conveyance robot R2, the transfer stage WS, and the first conveyance robot R1. Note that the underlying film forming step (S101) and the imprint step (S102) can be concurrently executed.

The operation of the film forming apparatus 1 will be described next with respect to FIG. 18. In step S201, the mold 300 is loaded into the film forming apparatus 1 and held by the mold holding unit 102. In step S202, the unprocessed substrate 400 is loaded into the film forming apparatus 1 and held by the substrate holding unit 106. In step S203, a curable composition CU is placed on the substrate 400 held by the substrate holding unit 106. In step S204, the mold 300 held by the mold holding unit 102 and the substrate 400 held by the substrate holding unit 106 are aligned (alignment). In step S205, the mold 300 (the contact surface 302) held by the mold holding unit 102 is brought into contact with the curable composition CM placed on the substrate (contact step). In step S206, while the curable composition CM on the substrate is in contact with the mold 300, the curable composition CM is cured (curing step). In step S206, the mold 300 is separated from the cured curable composition CM on the substrate (separation step). This forms the underlying film 402 (or 422) including the bank portion 406 (or the groove portion 424). In step S208, the substrate 400 on which the underlying film 402 is formed is unloaded from the film forming apparatus 1 and conveyed to the imprint apparatus 2. In step S209, it is determined whether there is the next substrate 400 (the unprocessed substrate 400) on which the underlying film 402 should be formed. If there is the next substrate 400, the process shifts to step S202 to load the next substrate 400 to the film forming apparatus 1. If there is no next substrate 400, the process shifts to step S210 to unload the mold 300 from the film forming apparatus 1.

The operation of the imprint apparatus 2 will be described next with reference to FIG. 19. In step S301, the mold 500 is loaded into the imprint apparatus 2 and held by the mold holding unit 202. In step S302, the substrate 400 on which the underlying film 402 (or the underlying film 422) is formed is loaded from the film forming apparatus 1 and held by the substrate holding unit 206. In step S303, the imprint material IM is placed on the inside region 408 (or 426) surrounded by the bank portion 406 (or the groove portion 424) of the underlying film 402 formed on the substrate 400 held by the substrate holding unit 206. In step S304, the mold 500 held by the mold holding unit 202 and the substrate 400 held by the substrate holding unit 206 are aligned. In step S305, the mold 500 (the pattern region 502) held by the mold holding unit 202 is brought into contact with the imprint material IM placed on the substrate (contact step). In this case, since the bank portion 406 (or the groove portion 424) is provided on the underlying film 402 formed on the substrate 400, the imprint material IM is suppressed from protruding from the upper surface of the mesa portion 504. In step S306, while the imprint material IM on the substrate is in contact with the mold 500, the imprint material IM is cured (curing step). In step S306, the mold 500 is separated from the cured imprint material IM on the substrate (separation step). This forms the pattern 410 (or 428) of the imprint material IM is formed on the substrate (shot region). In step S308, it is determined whether there is a next shot region on which the pattern 410 of the imprint material IM should be formed. If there is a next short region, the process shifts to step S303 to place the imprint material IM on the next shot region (the inside region 408 (426) surrounded by the bank portion 406 (or the groove portion 424) of the underlying film 402 (or 422)). If there is a next shot region, the process shifts to step S309 to unload the substrate 400 (the processed substrate 400) on which the pattern 410 of the imprint material IM is formed from the imprint apparatus 2 and convey the substrate 400 to the unload port UP. In step S310, it is determined whether there is a next substrate 400 on which the pattern 410 of the imprint material IM should be formed. If there is the next substrate 400, the process shifts to step S302 to load the next substrate 400 into the imprint apparatus 2. If there is no next substrate 400, the process shifts to step S311 to unload the mold 500 from the imprint apparatus 2.

The present embodiment has exemplified, as the imprint system 3, the arrangement including the one film forming apparatus 1 and the one imprint apparatus 2. However, the imprint system 3 may use an arrangement including a plurality of film forming apparatuses 1 and a plurality of imprint apparatuses 2, a so-called cluster arrangement. When the imprint system 3 uses a cluster arrangement, especially in a case where the arrangement includes a plurality of film forming apparatuses 1, it is possible to reduce (planarize) a stepped portion on a substrate by making each of the two different film forming apparatuses 1 execute an underlying film forming step (a total of two times of an underlying film forming step). For example, the first film forming apparatus (the first underlying film forming step) forms an underlying film that does not include the bank portion 406 or the groove portion 424. The second film forming apparatus (the second underlying film forming step) then forms, on the underlying film, an underlying film including the bank portion 406 and the groove portion 424. Alternatively, the first film forming apparatus may form an underlying film including the bank portion 406 and the groove portion 424. The second film forming apparatus may further form, on the underlying film, an underlying film including the bank portion 406 and the groove portion 424. Alternatively, the first film forming apparatus may form an underlying film including the bank portion 406 and the groove portion 424. The second film forming apparatus may further form, on the underlying film, an underlying film that does not include the bank portion 406 and the groove portion 424. Although the present embodiment has exemplified the case where the two different film forming apparatuses 1 execute two times of an underlying film forming step, one film forming apparatus 1 may execute two times of an underlying film forming step.

As has been described above, the present embodiment provides a new technique for suppressing an imprint material placed on a substrate from protruding from a mold and adhering to a side surface of the mold.

An article manufacturing method includes a forming step of forming a pattern on a substrate by using the imprint system 3 described above, a processing step of processing the substrate on which the pattern is formed in the forming step, and a manufacturing step of manufacturing an article from the substrate processed in the processing step. In the forming step, the above pattern forming method is used.

The cured film having a pattern formed by the pattern forming method of the present disclosure can directly be used as at least a partial constituent member of various kinds of articles. Also, the cured film having a pattern formed by the pattern forming method of the present disclosure can temporarily be used as a mask for etching or ion implantation with respect to the substrate (a layer to be processed when the substrate has the layer to be processed). This mask is removed after etching or ion implantation is performed in a processing step of the substrate. Consequently, various kinds of articles can be manufactured.

When removing a cured product in recesses of a pattern of the cured product by etching, a practical method is not particularly limited, and a conventionally known method such as dry etching can be used. A conventionally known dry etching apparatus can be used in this dry etching. A source gas for dry etching is appropriately selected in accordance with an element composition of the cured product to be etched. More specifically, it is possible to use halogen gases such as CF₄, C₂F₆, C₃F₈, CCl₂F₂, CCl₄, CBrF₃, BCl₃, PCl₃, SF₆, and Cl₂ as the source gas. As the source gas, it is also possible to use gases containing oxygen atoms such as O₂, CO, and CO₂, inert gases such as He, N₂, and Ar, and gases such as H₂ and NH₃ as the source gas. Note that these gases can also be mixed and used as the source gas. In this case, the photo-cured film is required to have a high dry etching resistance in order to process the base substrate with high yield.

An article is, for example, an electric circuit element, an optical element, MEMS, a recording element, a sensor, or a mold. Examples of the electric circuit element are volatile or nonvolatile semiconductor memories such as a DRAM, an SRAM, a flash memory, and an MRAM, and semiconductor elements such as an LSI, a CCD, an image sensor, and an FPGA. Examples of the optical element are a micro lens, a light guide body, a waveguide, an antireflection film, a diffraction grating, a polarizer, a color filter, a light-emitting element, a display, and a solar battery. Examples of the MEMS are a DMD, a microchannel, and an electromechanical transducer. Examples of the recording element are optical disks such as a CD and a DVD, a magnetic disk, a magneto-optical disk, and a magnetic head. Examples of the sensor are a magnetic sensor, a photosensor, and a gyro sensor. An example of the mold is a mold for imprinting.

While the present disclosure has been described with reference to exemplary embodiments, it is to be understood that the preset disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-166565 filed on September 25, 2024, which is hereby incorporated by reference herein in its entirety.

What is claimed is:

1. A pattern forming method of forming patterns on a plurality of shot regions on a substrate, the method comprising:
forming a film including a bank portion surrounding each of the plurality of shot regions on the substrate; and
forming the pattern by placing an imprint material on an inside region surrounded by the bank portion on the film formed in the forming the film and bringing the imprint material into contact with a mold.

2. The method according to claim 1, wherein the film includes an underlying film for reducing a stepped portion on the substrate.

3. The method according to claim 2, wherein in the forming the film, the film covering an entire region of the substrate is formed by pressing a curable composition placed on the substrate with a mold different from the mold used in the forming the pattern.

4. The method according to claim 1, wherein the bank portion is formed of a plurality of convex patterns.

5. The method according to claim 4, wherein an interval between the plurality of convex patterns is smaller than a radius of a droplet of the imprint material arranged in the forming the pattern.

6. The method according to claim 1, wherein the mold includes a concave portion surrounding a pattern region provided with a pattern corresponding to the pattern.

7. The method according to claim 6, wherein the concave portion is provided in the mold so as to face the bank portion through the imprint material in the forming the pattern.

8. The method according to claim 6, wherein the concave portion is provided in the mold so as to face an inside region surrounded by the bank portion on the film through the imprint material.

9. The method according to claim 6, wherein the bank portion has a height larger than a height of the pattern of the mold by not less than 5 nm.

10. The method according to claim 1, wherein the film includes a first convex portion on an upper surface of the bank portion,
the mold includes a second convex portion surrounding a pattern region provided with a pattern corresponding to the pattern, and
the second convex portion is provided on the mold in the forming the pattern so as to face a region in which the first convex portion on the upper surface is not present through the imprint material, while part of a side surface of the second convex portion faces part of a side surface of the first convex portion through the imprint material.

11. The method according to claim 1, wherein the film includes an outer peripheral bank portion provided along an outer periphery of the substrate and surrounding the plurality of shot regions.

12. A pattern forming method of forming patterns on a plurality of shot regions on a substrate, the method comprising:
forming a film including a groove portion surrounding each of the plurality of shot regions on the substrate; and
forming the pattern by placing an imprint material on an inside region surrounded by the groove portion on the film formed in the forming the film and bringing the imprint material into contact with a mold.

13. A mold used to form a film on a substrate having a plurality of shot regions, the mold having a surface configured to come into contact with a curable composition to form the film,
wherein the surface includes a concave portion or a convex portion provided so as to surround a region facing each of the plurality of shot regions while the mold faces the substrate.

14. A system that forms patterns on a plurality of shot regions on a substrate, the system comprising:
a film forming apparatus configured to form a film including a bank portion surrounding each of the plurality of shot regions on the substrate; and
an imprint apparatus configured to form the pattern by placing an imprint material on an inside region surrounded by the bank portion on the film formed by the film forming apparatus and bringing the imprint material and a mold into contact with each other.

15. A system that forms patterns on a plurality of shot regions on a substrate, the system comprising:
a film forming apparatus configured to form a film including a groove portion surrounding each of the plurality of shot regions on the substrate; and
an imprint apparatus configured to form the pattern by placing an imprint material on an inside region surrounded by the groove portion on the film formed by the film forming apparatus and bringing the imprint material and a mold into contact with each other.

16. An article manufacturing method comprising:
forming a pattern on a substrate by using a system defined in claim 14;
processing the substrate after the pattern is formed thereon; and
manufacturing an article from the processed substrate.
